(19) United States
(12) Patent Application Publication
(10) Pub. No.: US 2015/0001495 A1
(43) Pub. Date: Jan. 1, 2015

(54) DONOR SUBSTRATE FOR TRANSFER AND MANUFACTURING METHOD OF ORGANIC LIGHT EMITTING DIODE DISPLAY

(71) Applicant: Samsung Display Co., Ltd., Yongin-City (KR)

(72) Inventors: Ji-Young CHOUNG, Yongin-City (KR); Hyun-Sung BANG, Yongin-City (KR); Yeon-Hwa LEE, Yongin-City (KR); Joon-Gu LEE, Yongin-City (KR); Jin-Baek CHOI, Yongin-City (KR); Young-Woo SONG, Yongin-City (KR); Jong-Hyuk LEE, Yongin-City (KR)

(73) Assignee: SAMSUNG DISPLAY CO., LTD., Yongin-City (KR)

(21) Appl. No.: 14/276,327

(22) Filed: May 13, 2014

(30) Foreign Application Priority Data
Jul. 1, 2013 (KR) 10-2013-0076607

(51) Int. Cl. H01L 27/32; H01L 51/56; H01L 51/52

(52) U.S. Cl. CPC H01L 27/3244; H01L 51/5271; H01L 51/56
USPC 257/40; 438/29

(57) ABSTRACT

A donor substrate for transfer and a manufacturing method of an organic light emitting diode (OLED) display, the donor substrate including a transparent support layer; a light-to-heat conversion layer on one side of the support layer, the light to heat conversion layer being in the form of a first pattern; a transfer layer covering the light-to-heat conversion layer; and a reflection layer on another side of the support layer, the other side being opposite to the one side of the support layer, the reflection layer being in the form of a second pattern.

### CROSS-REFERENCE TO RELATED APPLICATION

Korean Patent Application No. 10-2013-0076607, filed on Jul. 1, 2013, in the Korean Intellectual Property Office, and entitled: “Donor Substrate for Transfer and Manufacturing Method of Organic Light Emitting Diode Display,” is incorporated by reference herein in its entirety.

### BACKGROUND

1. Field

Embodiments relate to a donor substrate for transfer and a manufacturing method of an OLED display.

2. Description of the Related Art

A display device may display an image using a combination of light emitted from a plurality of pixels. In the OLED display, each pixel may be formed of a pixel circuit and an organic light emitting diode of which operation is controlled by the pixel circuit. The organic light emitting diode may include a pixel electrode, an organic emission layer, and a common electrode.

One of the pixel electrode and the common electrode may be a hole injection electrode (anode) and the other may be an electron injection electrode (cathode). Holes injected from the anode and electrons injected from the cathode may be combined in the organic emission layer to generate exciton, and light emission may be performed while the exciton discharges energy.

The above information disclosed in this Background section is only for enhancement of understanding of the background of the described technology and therefore it may contain information that does not form the prior art that is already known in this country to a person of ordinary skill in the art.

### SUMMARY

Embodiments are directed to a donor substrate for transfer and a manufacturing method of an OLED display.

The embodiments may be realized by providing a donor substrate for transfer, the donor substrate including a transparent support layer; a light-to-heat conversion layer on one side of the support layer, the light to heat conversion layer being in the form of a first pattern; a transfer layer covering the light-to-heat conversion layer; and a reflection layer on another side of the support layer, the other side being opposite to the one side of the support layer, the reflection layer being in the form of a second pattern.

The first pattern may be the same as a pattern of a transfer target, and the second pattern may include an opening aligned with the first pattern.

The transfer layer may include an organic light emitting material, and the first pattern of the light-to-heat conversion layer may have the same shape and the same size as a size and shape as transfer target organic emission layers.

The support layer may include a plurality of concave grooves, and the light-to-heat conversion layer and the transfer layer may be formed in each of the plurality of concave grooves.

The support layer may include a groove portion between the plurality of concave grooves, the groove portion having a depth larger than a depth of each of the plurality of concave grooves.

The transfer layer may include a metal material, and the first pattern of the light-to-heat conversion layer may have the same shape as a transfer target auxiliary electrode.

The support layer may include a concave groove, and the light-to-heat conversion layer and the transfer layer may be formed in the concave groove.

The concave groove and the first pattern of the light-to-heat conversion may have a shape of a stripe or a lattice.

The support layer may include one of glass, quartz, or a polymer material.

The embodiments may also be realized by providing a manufacturing method of an organic light emitting diode (OLED) display, the method including forming a pixel electrode and a pixel defining layer on a substrate; preparing a first donor substrate for transfer such that the first donor substrate for transfer includes a support layer, a light-to-heat conversion layer on one side of the support layer, the light to heat conversion layer having a same shape as an organic emission layer to be formed, a transfer layer covering the light-to-heat transfer layer, and a reflection layer on another side of the support layer, the other side being opposite to the one side of the support layer, the reflection layer including an opening aligned with the light-to-heat conversion layer; arranging the first donor substrate for transfer on the substrate such that the light-to-heat conversion layer and the transfer layer face the pixel electrode; and irradiating light to the first donor substrate for transfer and forming the organic emission layer by transferring the transfer layer onto the pixel electrode using heat from the light-to-heat conversion layer.

The support layer may include a plurality of concave grooves, and the light-to-heat conversion layer and the transfer layer may be foamed in each of the plurality of concave grooves.

The manufacturing method may further include forming a spacer on the pixel defining layer, and forming a groove portion in the support layer, such that arranging the first donor substrate for transfer on the substrate causes the groove portion to face the spacer.

A width of the groove portion may be smaller than a width of each of the concave grooves, and a depth of the groove portion may be greater than a depth of each of the concave grooves.

The manufacturing method may further include forming a common electrode on the organic emission layer; preparing a second donor substrate for transfer such that the second donor substrate for transfer includes a support layer, a light-to-heat conversion layer on one side of the support layer, the light-to-heat conversion layer having a same shape as an auxiliary electrode to be formed, a transfer layer covering the light-to-heat conversion layer, and a reflection layer on another side of the support layer, the other side being opposite to the one side of the support layer, the reflection layer including an opening aligned with the light-to-heat conversion layer; arranging the second donor substrate for transfer on the substrate such that the light-to-heat conversion layer and the transfer layer face the common electrode; and irradiating light to the second donor substrate for transfer and forming the auxiliary electrode by transferring the transfer layer onto to the common electrode using heat from the light-to-heat conversion layer.

The support layer may include a concave groove, and the light-to-heat conversion layer and the transfer layer may be formed in the concave groove.

The concave groove and the light-to-heat conversion layer may have a shape of a stripe or a lattice.

### BRIEF DESCRIPTION OF THE DRAWINGS

Features will be apparent to those of skill in the art by describing in detail exemplary embodiments with reference to the attached drawings in which:

FIG. 1 illustrates a partial cross-sectional view of a donor substrate for transfer according to a first exemplary embodiment.

FIG. 2 illustrates a partial top plan view of a light to heat conversion layer in the transfer donor substrate shown in FIG. 1.

FIG. 3 illustrates a partial top plan view of a reflection layer in the transfer donor substrate shown in FIG. 1.

FIG. 4 illustrates a schematic diagram of the transfer donor substrate shown in FIG. 1 and a transfer target substrate.

FIG. 5 illustrates a partial top plan view of the light to heat conversion layer and a groove portion in the transfer donor substrate shown in FIG. 1.

FIG. 6 illustrates a partial cross-sectional view of a donor substrate for transfer according to a second exemplary embodiment.

FIG. 7 illustrates a partial top plan view of a light to heat conversion layer in the transfer donor substrate of FIG. 6.

FIG. 8 illustrates a partial top plan view of a reflection layer in the transfer donor substrate of FIG. 6.

FIG. 9 illustrates a flowchart of a manufacturing method of an organic light emitting diode display according to a third exemplary embodiment.

FIG. 10 illustrates a partially enlarged cross-sectional view of the organic light emitting diode display in the first step of FIG. 9.

FIG. 11 illustrates a partially enlarged cross-sectional view of the organic light emitting diode display in the second and third steps of FIG. 9.

FIG. 12 illustrates a partially enlarged cross-sectional view of the organic light emitting diode display in the fourth step of FIG. 9.

FIG. 13 illustrates a flowchart of a manufacturing method of an organic light emitting diode display according to a fourth exemplary embodiment.

FIG. 14 illustrates a partially enlarged cross-sectional view of the organic light emitting diode display in the fifth step of FIG. 13.

FIG. 15 illustrates a partially enlarged cross-sectional view of the organic light emitting diode display in the fifth to seventh steps of FIG. 13.

FIG. 16 illustrates a partially enlarged cross-sectional view of the organic light emitting diode display in the eighth step of FIG. 13.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

In addition, unless explicitly described to the contrary, the word “comprise” and variations such as “comprises” or “comprising”, will be understood to imply the inclusion of stated elements but not the exclusion of any other elements. It will be understood that when an element such as a layer, film, region, or substrate is referred to as being “on” another element, it can be directly on the other element or intervening elements may also be present. In contrast, when an element is referred to as being “directly on” another element, there may be no intervening elements present.

Further, in the specification, the word “on” means positioning on or below the object portion, but does not essentially mean positioning on the upper side of the object portion based on a gravity direction.

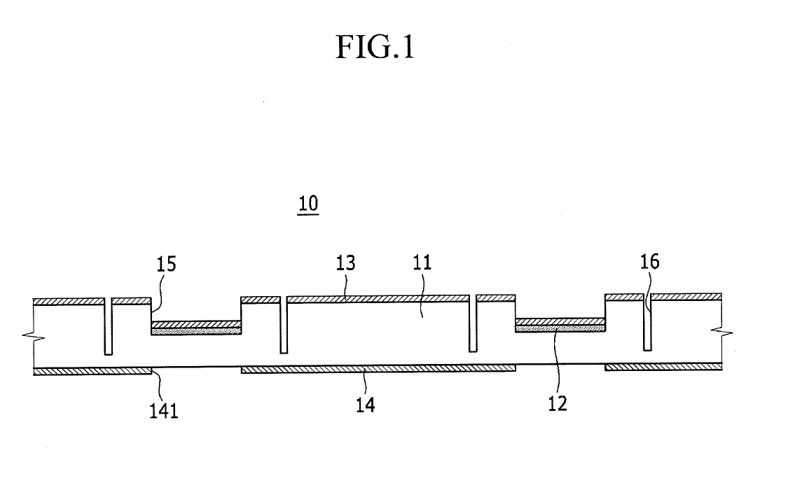

FIG. 1 illustrates a partial cross-sectional view of a donor substrate for transfer according to a first exemplary embodiment. Hereinafter, the donor substrate for transfer will be referred to as a transfer donor substrate. Referring to FIG. 1, a transfer donor substrate 10 may include, e.g., a support layer 11, a light-to-heat conversion layer (LTHC) 12, a transfer layer 13, and a reflection layer 14.

The support layer 11 may be transparent for transmission of light to the light-to-heat conversion layer 12, and may be formed of a mechanically stable material. For example, the support layer 11 may be made of glass or quartz, or may be made of a transparent polymer material such as polyester, polyacryl, polyepoxy, polyethylene, polystyrene, and polyethylene terephthalate.

The light-to-heat conversion layer 12 may absorb light in an infrared-visible ray area and may convert the absorbed light to heat energy. In an implementation, the light-to-heat conversion layer 12 may include, e.g., a metal that further includes an aluminum oxide or an aluminum sulfide, carbon black, graphite, or a polymer that further includes an infrared ray dye as a light absorbing material. The light-to-heat conversion layer 12 may have a single-layered or multi-layered structure.

The light-to-heat conversion layer 12 may be formed as a first pattern in or on one side of the support layer 11. The first pattern may be the same (e.g., size and shape) as a pattern of a transfer target. For example, when an organic emission layer is to be formed with the transfer donor substrate 10, the light-to-heat conversion layer 12 may be formed as a pattern that is the same as the pattern of the organic emission layer to be formed.

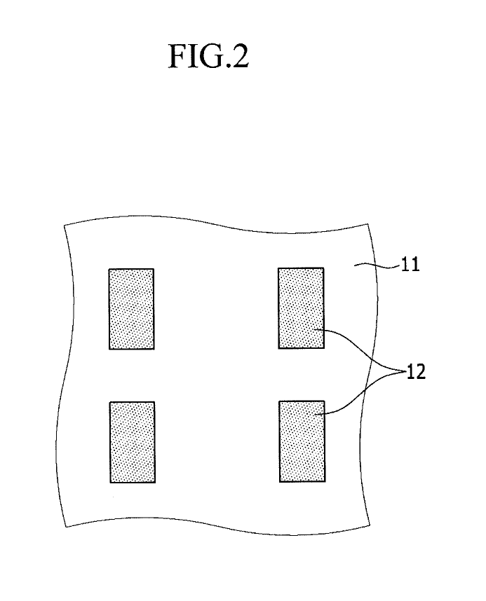

FIG. 2 illustrates a partial top plan view of the light-to-heat conversion layer in the transfer donor substrate of FIG. 1. Referring to FIG. 2, the light-to-heat conversion layer 12 may be patterned to be the same (e.g., size and shape) as an organic emission layer to be formed. For example, one light-to-heat conversion layer 12 may correspond to one pixel.

Referring to FIG. 1, the transfer layer 13 may be formed throughout or on the one side of the support layer 11, and may cover the light-to-heat conversion layer 12. The transfer layer 13 may be separated from the support layer 11 by heat energy supplied from the light-to-heat conversion layer 12, and may be transferred to a transfer target substrate (e.g., a substrate of an organic light emitting diode display). The transfer layer 13 may include an organic light emitting material.

Alternatively, the transfer layer 13 may be formed of a material for forming one of a hole injection layer (HIL), a hole transport layer (HTL), an electron transport layer (ETL), or an electron injection layer (EIL). In this case, one of the hole injection layer (HIL), the hole transport layer (HTL), the electron transport layer (ETL), or the electron injection layer (EIL) may be formed on the transfer target substrate using the transfer donor substrate 10.

The reflection layer 14 may reflect light irradiated to the transfer donor substrate 10. The reflection layer 14 may include, e.g., aluminum, aluminum alloy, silver, or a silver alloy. The reflection layer 14 may be formed as a second pattern on an opposite side of the support layer 11, e.g., opposite to the one side of the support layer 11 that includes the light-to-heat conversion layer 12. The second pattern may have an opposite or complementary shape, relative to the first pattern. For example, the reflection layer 14 may form or may include an opening 141 therein that corresponds to or is aligned with the light-to-heat conversion layer 12 on the one side of the support layer 11.

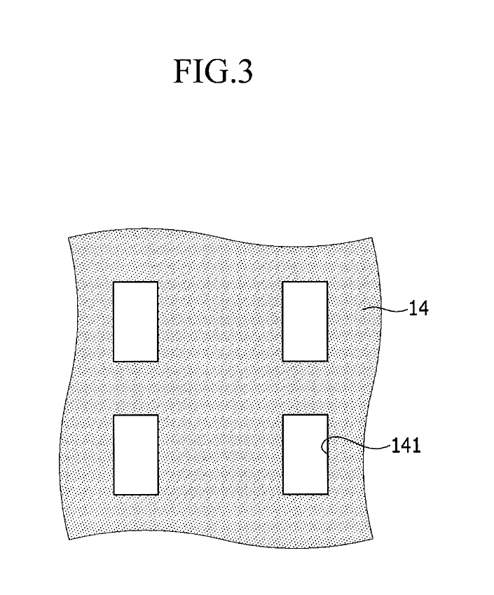

FIG. 3 illustrates a partial top plan view of the reflection layer in the transfer donor substrate of FIG. 1. Referring to FIG. 1 and FIG. 3, the reflection layer 14 may form or may include a plurality of openings 131 respectively having the same shape and the same size as the light-to-heat conversion layer 12 and in the same location as or aligned with the light-to-heat conversion layer 12.

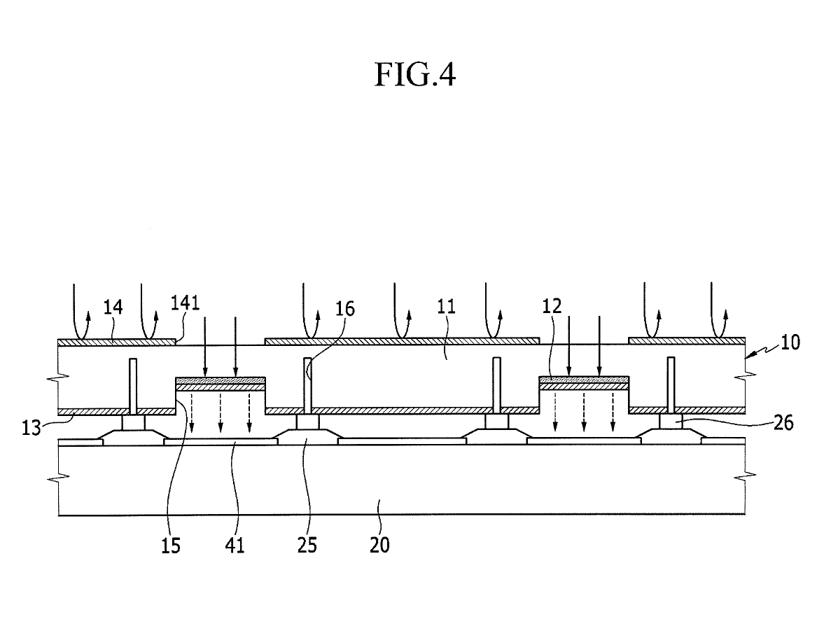

FIG. 4 illustrates a schematic diagram of the transfer donor substrate of FIG. 1 and a transfer target substrate. Referring to FIG. 4, the transfer target substrate 20 (hereinafter, referred to as a substrate includes a plurality of pixel electrodes 41 and a pixel defining layer 25 partitioning a pixel area). The transfer donor substrate 10 may be arranged on the substrate 20 so as to face a pixel electrode 41 at a given pixel, and a light source (not shown) may be disposed at an external side of the transfer donor substrate 10 so as to face the reflection layer 14.

Among light emitted from the light source, light that reaches the reflection layer 14 may be reflected by the reflection layer 14, and light that reaches to the opening 141 may be provided to the light-to-heat conversion layer 12 through the support layer 11. The light-to-heat conversion layer 12 may absorb light and may convert the light to heat energy. In an implementation, the transfer layer 13 may be transferred onto the substrate 20 while or by being evaporated by heat from the light-to-heat conversion layer 12.

In some transfer donor substrates, the light-to-heat conversion layer and the reflection layer may be in contact with each other on a same side of the support layer. For example, one of the light-to-heat conversion layer or the reflection layer may be patterned and the other of the light-to-heat conversion layer or the reflection layer foamed throughout or completely covering one side of the support layer. The reflection layer may be a metal layer having high heat conductivity, and heat generated from the light-to-heat conversion layer may be easily transmitted to the reflection layer. Therefore, an unexpected portion of the transfer layer may also be evaporated so that transfer precision may be deteriorated.

According to an embodiment, the light-to-heat conversion layer 12 and the reflection layer 14 may be formed on opposite sides of the support 11 in the transfer donor substrate 10 so that they may not contact each other. In addition, the light-to-heat conversion layer 12 and the reflection layer 14 may be patterned into shapes that are opposite or complementary to each other. Therefore, heat of the light-to-heat conversion layer 12 may not be conducted to the reflection layer 14, thereby precisely evaporating only a desired portion of the transfer layer 13, e.g., a portion contacting the light-to-heat conversion layer 12.

In this case, when a heat-resistive material, e.g., glass or quartz, is used as the support layer 11, conduction of heat from the light-to-heat conversion layer 12 to a peripheral area may be effectively blocked. As described, the transfer donor substrate 10 according to the present exemplary embodiment may help improve transfer precision so that a high-resolution organic emission layer may be easily formed.

In an implementation, the transfer donor substrate 10 may form or may include a concave groove 15 in the one side of the support layer 11, and the light-to-heat conversion layer 12 may be disposed in the concave groove 15 so that a diffusion angle of the transfer layer 13 may be limited. The concave groove 15 may have the same shape as the light-to-heat conversion layer 12 in the same location as the light-to-heat conversion layer 12, and may form a vertical side wall. The light-to-heat conversion layer 12 and the transfer layer 13 above or on the light-to-heat conversion layer 12 may be separated from one, e.g., outer, side of the support layer 11 by as much as the depth of the concave groove 15.

When the transfer layer 13 is evaporated by heat from the light-to-heat conversion layer 12, a divergence range may be limited by the side wall of the concave groove 15. Therefore, when the organic emission layer is foamed by transferring the transfer layer 13, the organic emission layer may not interrupt or interfere with a neighboring pixel, and may have a uniform thickness within the corresponding pixel. An organic light emitting diode (OLED) display including such an organic emission layer may exhibit improved color purity, color life-span, and luminous efficiency, and light emission uniformity in a pixel may be improved.

In an implementation, a spacer 26 may be formed on the pixel defining layer 25. In addition, the transfer donor substrate 10 may include a groove portion 16 having a narrow width in a portion facing and/or corresponding to the spacer 26. The groove portion 16 may correspond to an interface between pixel areas, and therefore one or a plurality of groove portions 16 may be provided between neighboring light-to-heat conversion layers 12.

The groove portion 16 in the support layer 11 may help suppress conduction of heat from the light-to-heat conversion layer 12 to a peripheral area. For example, when the support layer 11 is formed of a heat-resistive material, heat from the light-to-heat conversion layer 12 may be partially conducted to the peripheral area, and the heat conduction through the support layer 11 may be effectively blocked by forming the groove portions 16.

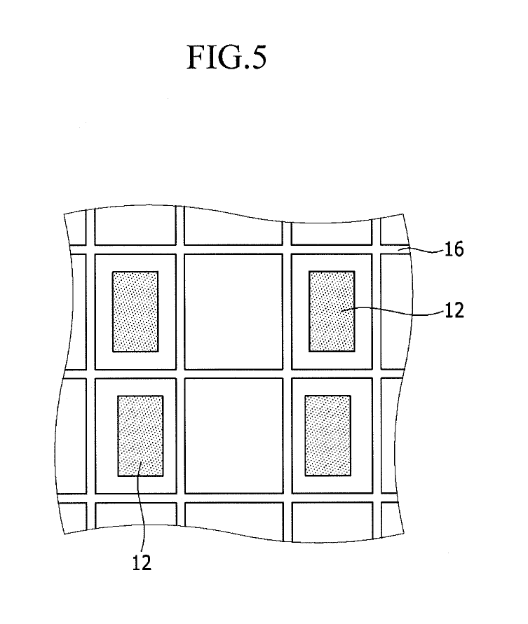

FIG. 5 illustrates a partial top plan view of the light-to-heat conversion layer and the groove portions in the transfer donor substrate of FIG. 1. Referring to FIG. 4 and FIG. 5, the groove portion 16 may be formed in the shape of a lattice corresponding to interfaces between pixel areas. A width of the groove portion 16 may be smaller than a width of the concave groove 15, and a depth of the groove portion 16 may be greater than a depth of the concave groove 15.

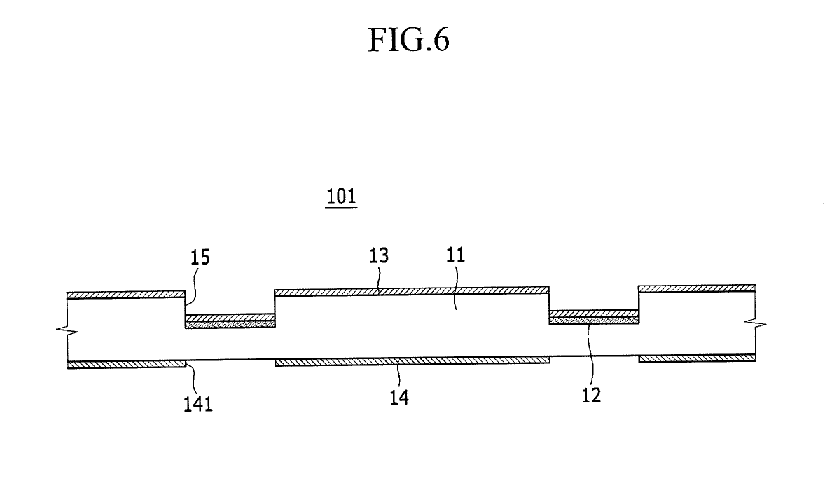

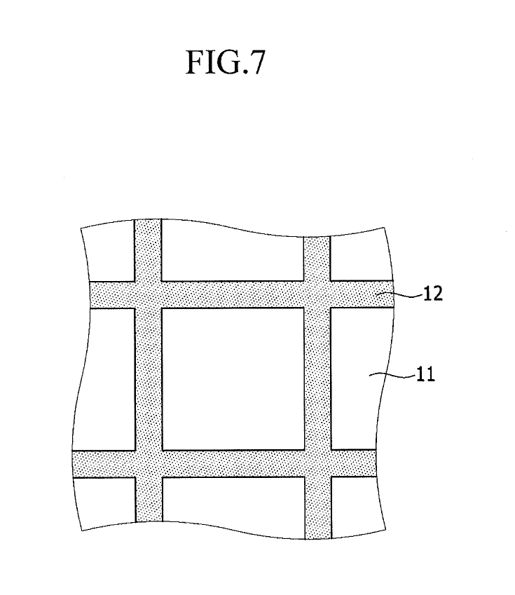

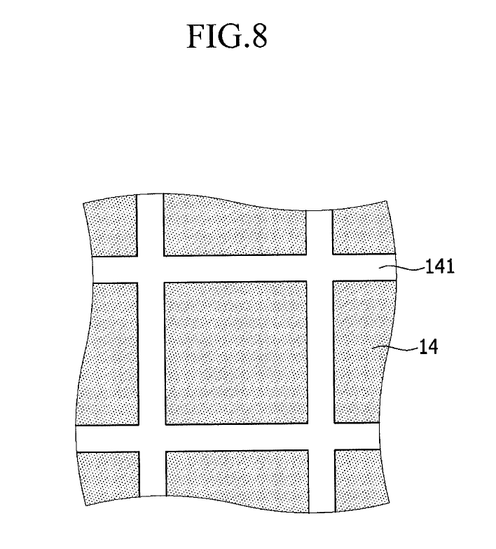

FIG. 6 illustrates a partial cross-sectional view of a transfer donor substrate according to a second exemplary embodiment. FIG. 7 and FIG. 8 illustrate partial top plan views of a light-to-heat conversion layer and a transfer layer in the transfer donor substrate of FIG. 6.

Referring to FIG. 6 to FIG. 8, a transfer donor substrate 101 according to the second exemplary embodiment may be similar to the transfer donor substrate of the first exemplary embodiment, except that the transfer donor substrate 101 may be used to form an auxiliary electrode on a common electrode. The same reference numerals are used for the same components as those of the first exemplary embodiment.

In an organic light emitting diode (OLED) display, an auxiliary electrode may be formed on a common electrode. The auxiliary electrode may help improve luminance uniformity by compensating for a voltage drop in a large-sized common electrode. The auxiliary electrode may be formed in the shape of a stripe or a lattice on the common electrode.

In the second exemplary embodiment, the transfer layer 13 may be made of a metal, e.g., may include aluminum, silver, gold, molybdenum, chromium, tungsten, or copper. A concave groove 15 and a light-to-heat conversion layer 12 may be formed in the shape of a stripe or a lattice on one side of a support layer 11, and a reflection layer 14 may be formed on an opposite side of the support layer 11 and may have an opposite or complementary shape relative to the light-to-heat conversion layer 12.

FIG. 7 illustrates that the light-to-heat conversion layer 12 may be formed in the shape of a lattice, and FIG. 8 illustrates that the reflection layer 14 may be formed in the opposite or complementary shape relative the lattice-shaped light-to-heat conversion layer 12. For example, in FIG. 8, the reflection layer 14 may include lattice-shaped openings 141.

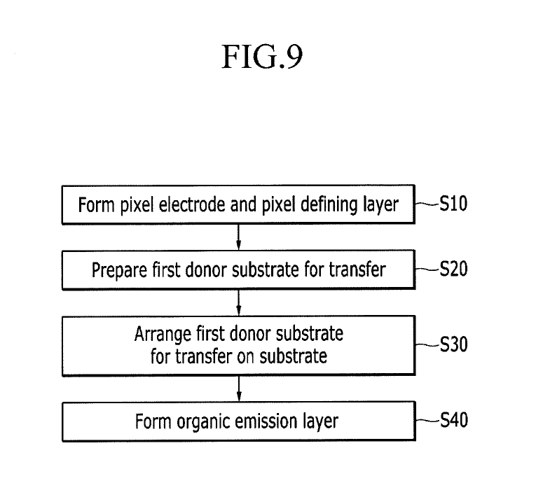

FIG. 9 illustrates a process flowchart of a manufacturing method of an OLED display according to a third exemplary embodiment.

Referring to FIG. 9, a manufacturing method of an OLED display may include a first step (S10) for forming a pixel electrode and a pixel defining layer on a substrate, a second step (S20) for preparing a first transfer donor substrate including a support layer, a light-to-heat conversion layer, a transfer layer, and a reflection layer, a third step (S30) for arranging the first transfer donor substrate on a substrate so as to make the light-to-heat conversion layer and the transfer layer face the pixel electrode, and a fourth step (S40) for irradiating light to the first transfer donor substrate and forming an organic emission layer by evaporating the transfer layer onto the pixel electrode using heat from the light-to-heat conversion layer.

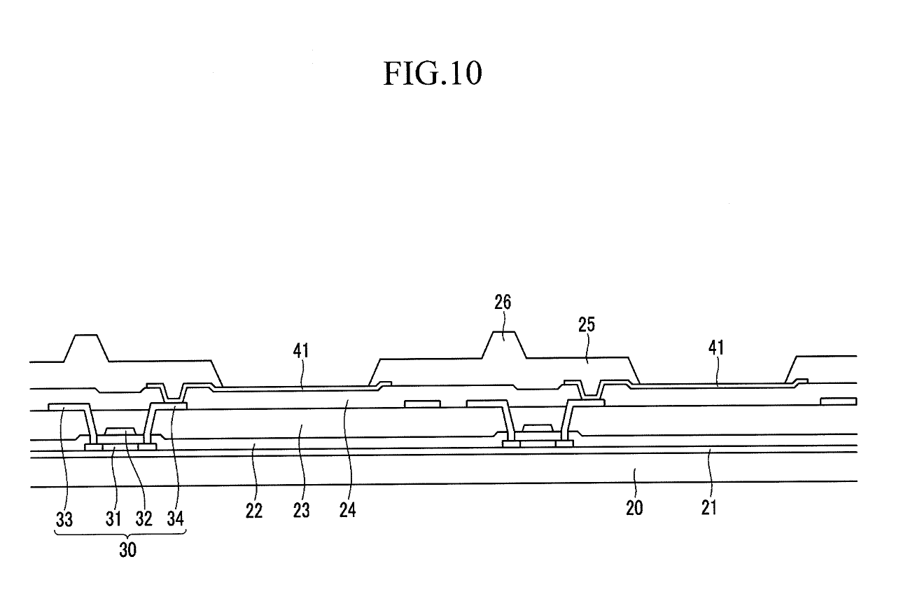

FIG. 10 illustrates a partially enlarged cross-sectional view of the OLED display in the first step of FIG. 9.

Referring to FIG. 10, the substrate 20 may be, e.g., a rigid substrate such as glass or a flexible substrate such as a polymer film. A buffer layer 21 may be formed on the substrate 20. The buffer layer 21 may be formed as an inorganic layer, and may include, e.g., SiO₂ or SiNx. The buffer layer 21 may provide a flat surface for forming a pixel circuit, and may help suppress permeation of moisture and a foreign material into the pixel circuit.

A thin film transistor 30 and a capacitor (not shown) may be formed on the buffer layer 21. The thin film transistor 30 may include a semiconductor layer 31, a gate electrode 32, and a source and drain electrodes 33 and 34. The semiconductor layer 31 may be formed of polysilicon or an oxide semiconductor, and may include a channel area in which impurities are not doped and a source area and a drain area in which impurities are doped at both sides of the channel area. When the semiconductor layer 31 is formed of the oxide semiconductor, a separate passivation layer for protecting the semiconductor layer 31 may be added.

A gate insulating layer 22 may be formed between the semiconductor layer 31 and the gate electrode 32, and an interlayer insulating layer 23 may be formed between the gate electrode 32 and the source and drain electrodes 33 and 34. In an implementation, the thin film transistor 30 may have a top gate structure. The capacitor may include a first capacitor plate formed on the gate insulating layer 22 and a second capacitor plate formed on the interlayer insulating layer 23.

The thin film transistor 30 shown in FIG. 10 may be a driving thin film transistor, and the pixel circuit may further include a switching thin film transistor (not shown). The switching thin film transistor may be formed as a switching electrode for selection of a pixel for light emission, and the driving thin film transistor may apply power for light emission to the selected pixel. The pixel implies the minimum unit of light emission, and the pixel circuit may include at least two thin film transistors and at least one capacitor.

A planarizing layer 24 may be formed on the source and drain electrodes 33 and 34. The planarizing layer 24 may include an organic material, e.g., benzocyclobutene (BCB), acryl resin, epoxy resin, or phenol resin, or an inorganic material, e.g., SiNx. The planarizing layer 24 may form a via hole that partially exposes the drain electrode 34, and pixel electrodes 41 may be formed on the planarizing layer 24.

Each pixel electrode 41 may be formed in each pixel, and may be connected with the drain electrode 34 of the thin film transistor 30. The pixel defining layer 25 may partition pixel areas on the edges of the pixel electrodes 41. The organic emission layer may be formed through the second to fourth steps over a pixel electrode 41 that is exposed without being covered by the pixel defining layer 25. A spacer 26 may be formed on the pixel defining layer 25.

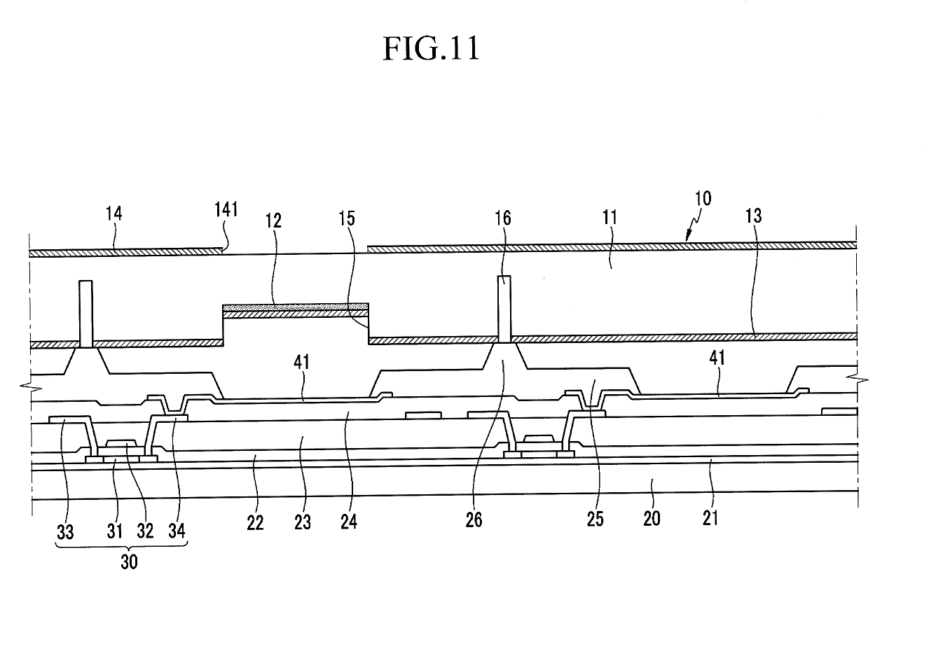

FIG. 11 illustrates a partially enlarged cross-sectional view of the OLED display in the second and third steps of FIG. 9.

Referring to FIG. 11, the first transfer donor substrate 10 may be the transfer donor substrate of the above-stated first exemplary embodiment. The transfer layer 13 may include an organic light emitting material, and the light-to-heat conversion layer 12 may be formed in the same shape of an organic emission layer to be formed. In addition, the reflection layer 14 may have the opposite or complementary shape relative to the light-to-heat conversion layer 12. The structure of the first transfer donor substrate 10 may be the same as that of the first exemplary embodiment, and therefore a repeated description thereof may be omitted.

The first transfer donor substrate 10 may be arranged on the substrate 20 to make the light-to-heat conversion layer 12 and the transfer layer 13 on the light-to-heat conversion layer 12 face the pixel electrode 41 of a transfer target pixel. The light-to-heat conversion layer 12 may be formed in a concave groove 15, and the support layer 11 may include a groove portion 16 in a portion thereof facing the spacer 26.

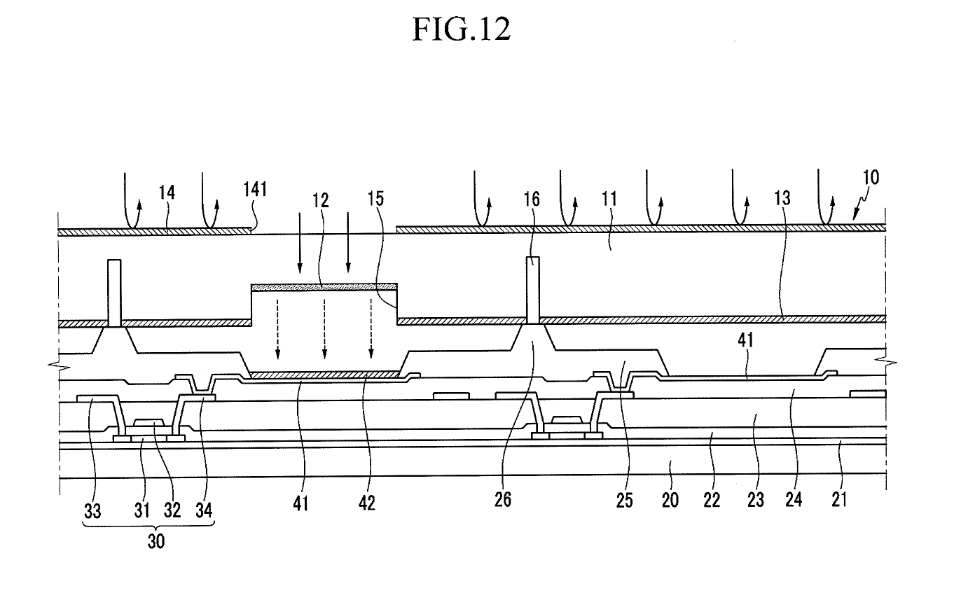

FIG. 12 illustrates a partially enlarged cross-sectional view of the OLED display in the fourth step of FIG. 9.

Referring to FIG. 12, a light source may be provided at an external side of the first transfer donor substrate 10 so as to face the reflection layer 14, and may irradiate light to the first transfer donor substrate 10. Then, some light emitted from the light source light that reaches the reflection layer 14 may be reflected by the reflection layer 14, and some light that passes through the support layer 11 may be converted to heat energy in the light-to-heat conversion layer 12. In addition, the transfer layer 13 on the light-to-heat conversion layer 12 may be transferred onto the pixel electrode 41 while being evaporated by heat from the light-to-heat conversion layer 12 such that an organic emission layer 42 is formed.

The organic emission layer 42 may be one of a red emission layer, a green emission layer, or a blue emission layer. Alternatively, the organic emission layer 42 may be a white emission layer, or may be formed in a layered structure of a red emission layer, a green emission layer, and/or a blue emission layer. When the organic emission layer 42 emits light of a white color, the OLED display may further include a color filter (not shown).

The first transfer donor substrate 10 may be provided for each color of the organic emission layer 42, and the second to fourth steps may be repeated for each color of the organic emission layer 42.

In the process for forming the organic emission layer 42, the light-to-heat conversion layer 12 may not contact the reflection layer 14 (which has high heat conductivity). Therefore, deterioration of transfer precision due to conduction of heat to the reflection layer 14 may be reduced and/or prevented. In addition, heat from the light-to-heat conversion layer 12 is conducted to the periphery area through the support layer 11, and therefore the groove portion 16 formed in the support layer 11 prevents heat conduction through the support layer 11. As described, conduction of the heat of the light-to-heat conversion layer 12 to the periphery area can be minimized so that pattern precision can be improved.

In addition, the light-to-heat conversion layer 12 and the transfer layer 13 on the light-to-heat conversion layer 12 may be formed in the concave groove 15, and a diffusion range may be limited in evaporation of the transfer layer 13 by a side wall of the concave groove 15. Thus, the organic emission layer 42 may be formed with a uniform thickness in the corresponding pixel without interrupting or interfering with a neighboring pixel. Therefore, the OLED display may exhibit improved color purity, a color life-span, and luminous efficiency, and light emission uniformity in the pixel may be improved.

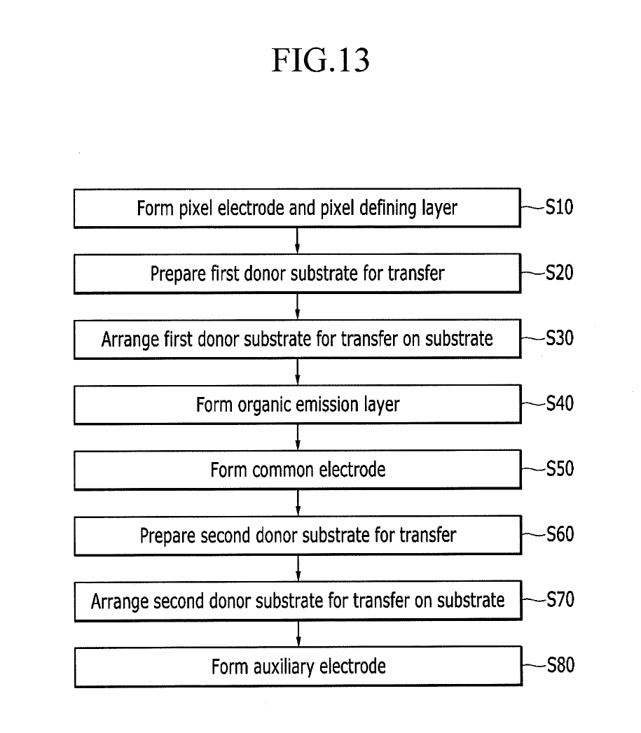

FIG. 13 illustrates a flowchart of a manufacturing method of an OLED display according to a fourth exemplary embodiment.

Referring to FIG. 13, a manufacturing method of an OLED display may further include a fifth step (S50) for forming a common electrode on an organic emission layer and a sixth step (S60) for preparing a second transfer donor substrate including a support layer, a light-to-heat conversion layer, a transfer layer, and a reflection layer in addition to the manufacturing method of the third exemplary embodiment. In addition, the manufacturing method may further include a seventh step (S70) for arranging the second transfer donor substrate on a substrate to make the light-to-heat conversion layer and the transfer layer face a common layer and an eighth step (S80) for irradiating light to the second transfer donor substrate and forming an auxiliary electrode by evaporating the transfer layer onto the common electrode.

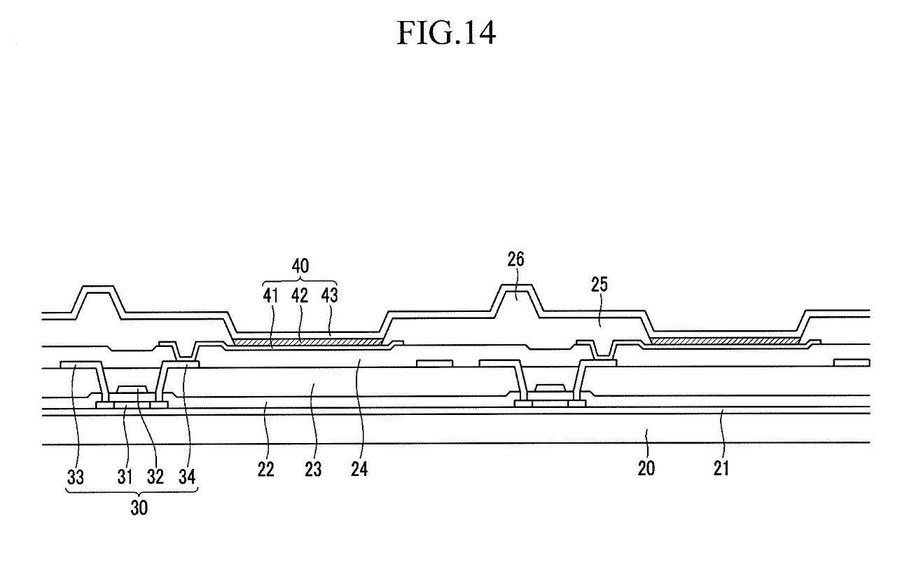

FIG. 14 illustrates a partially enlarged cross-sectional view of the OLED display in the fifth step of FIG. 13.

Referring to FIG. 14, a common electrode 43 may be formed in the entire display area on the organic emission layer 42 and the pixel defining layer 25. The pixel electrode 41, the organic emission layer 42, and the common electrode 43 may form an organic light emitting diode (OLED) 40. One of the pixel electrode 41 and the common electrode 43 may function as an anode that injects holes, and the other may function as a cathode that injects electrons. Holes injected from the anode and electrons injected from the cathode may be combined in the organic emission layer 42 to generate exciton, and light emission may be performed while the exciton discharges energy.

One of the pixel electrode 41 or the common electrode 43 may be formed as a reflection layer, and the other may be formed as a semi-transmissive layer or a transparent conductive layer. Light emitted from the organic emission layer 42 may be reflected by the reflection layer and passed through the semi-transmissive layer or the transparent conductive layer, and then emitted to the outside. In case of the semi-transmissive layer, light emitted from the organic emission layer 33 may be partially reflected to the reflective layer such that a resonance structure is formed.

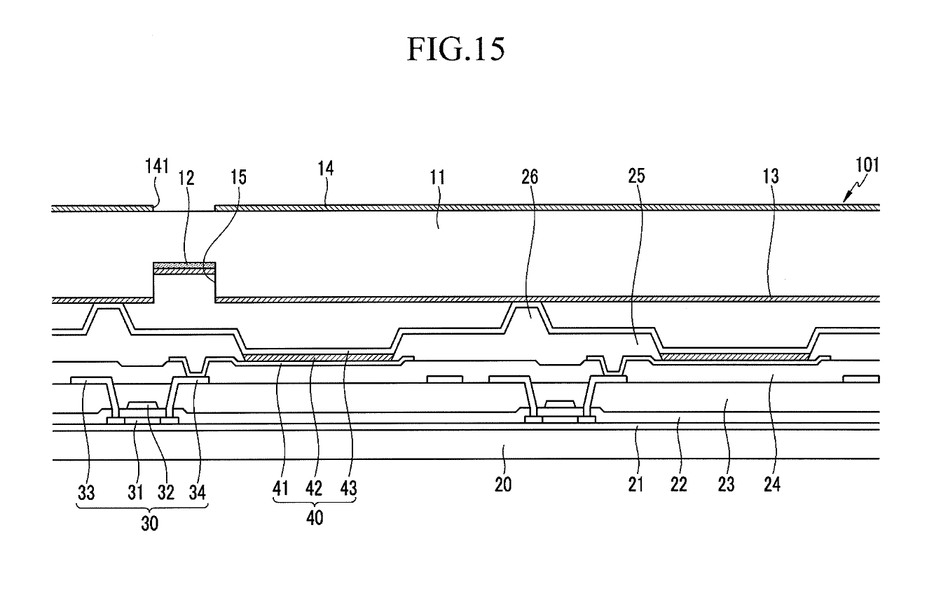

FIG. 15 illustrates a partially enlarged cross-sectional view of the OLED display in the fifth to seventh steps of FIG. 13.

Referring to FIG. 15, the second transfer donor substrate 101 may be the transfer donor substrate of the above-stated second exemplary embodiment. The transfer layer 13 may include a metallic material. The light-to-heat conversion layer 12 may have the same pattern of the auxiliary electrode, and the reflection layer 14 may include an opening 141 corresponding to, aligned with, or overlying the light-to-heat conversion layer 12. The structure of the second transfer donor substrate 101 may be the same as that of the second exemplary embodiment, and therefore a repeated description thereof may be omitted.

The second transfer donor substrate 101 may be arranged on the substrate 20 to make the light-to-heat conversion layer 12 and the transfer layer 13 on the light-to-heat conversion layer 12 face the common electrode 43.

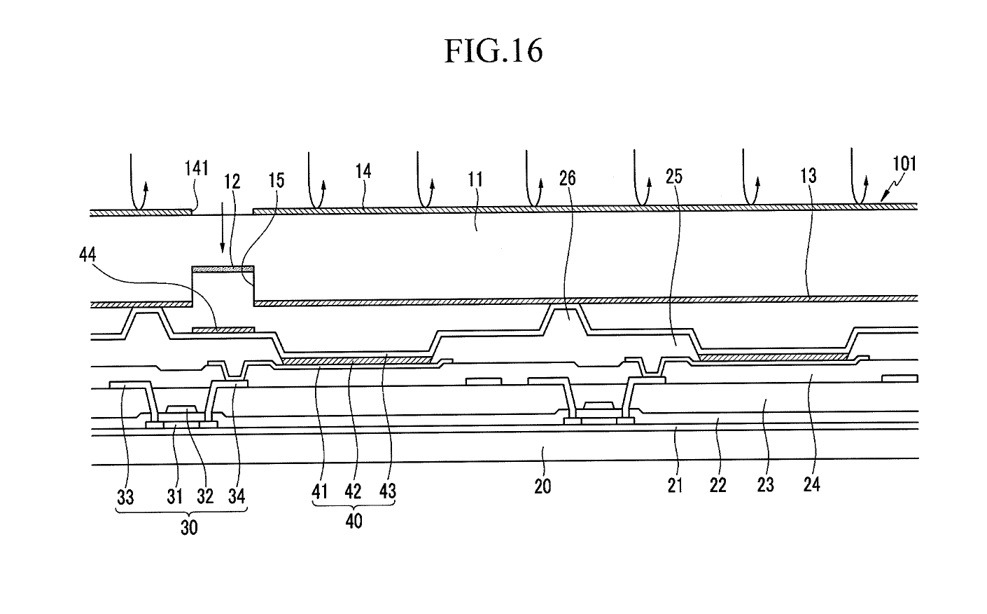

FIG. 16 illustrates a partially enlarged cross-sectional view of the OLED display in the eight step of FIG. 13.

Referring to FIG. 16, a light source may be disposed at an external side of the second transfer donor substrate 101 so as to face the reflection layer 14, and may irradiate light to the second transfer donor substrate 101. Then, some light emitted from the light source may reach the reflection layer 14 and be reflected by the reflection layer 14, and some light may pass through the support layer 11 to be converted to heat energy in the light-to-heat conversion layer 12. In addition, the transfer layer 13 on the light-to-heat conversion layer 13 may be transferred onto the common electrode 43 while being evaporated by heat of the light-to-heat conversion layer 12 such that an auxiliary electrode 44 is formed.

The auxiliary electrode 44 may help improve screen luminance uniformity by compensating for a voltage drop of a large-sized common electrode 43. The auxiliary electrode 44 may be formed in the shape of a stripe or a lattice on the common electrode 43.

In the process for forming the auxiliary electrode 44, the light-to-heat conversion layer 12 may not contact the reflection layer 14 having high heat conductivity, and therefore deterioration of transfer precision due to heat conduction to the reflection layer 14 may be reduced and/or prevented. In addition, the light-to-heat conversion layer 12 and the transfer layer 13 on the light-to-heat conversion layer 12 may be formed in the concave groove 15, and a diffusion range in evaporation of the transfer layer 13 may be limited by a side wall of the concave groove 15. Accordingly, a pattern precision of the auxiliary electrode 44 may be improved.

After the eighth step S80, the common electrode 43 may be covered by an encapsulation substrate or a thin film encapsulation layer. The encapsulation substrate or the thin film encapsulation layer may seal the organic light emitting diode 40 to help suppress deterioration of the organic light emitting diode 40 due to moisture and oxygen included in an external air.

When light of the organic emission layer 42 passes through the pixel electrode 41 and is emitted to the outside, a touch screen panel and/or optical films may be provided in an external side (e.g., the bottom side in FIG. 16) of the substrate 20. When the light of the organic emission layer 42 passes through the common electrode 43 and is emitted to the outside, a touch screen panel and/or optical films may be provided on the encapsulation substrate or the thin film encapsulation layer.

By way of summation and review, a method for forming an organic emission layer may include, e.g., a deposition method using a metal mask, a printing method such as an inkjet or a nozzle print, a heat transfer method using a donor substrate for transfer, or the like. Among the methods, the heat transfer method may have a relatively simple process, but may have difficulty in forming of a high-resolution organic emission layer pattern due to conduction of heat of the light-to-heat conversion layer to a periphery area.

In addition, evaporation of a part of the organic emission layer may be easily diffused to the periphery area due to heat of the light-to-heat conversion layer. Thus, the organic emission layer may overlap a neighboring pixel. In this case, color purity, color life-span, and luminous efficiency may be deteriorated. In addition, the organic emission layer may have a difference in thickness in a center portion and a peripheral area of the pixel, so that luminance uniformity in the pixel may be deteriorated.

The embodiments may provide a donor substrate for transfer that can form a high-resolution organic emission layer pattern by transferring an organic layer with high precision.

Conduction of heat of the light-to-heat conversion layer during the transfer process may be minimized so that pattern precision of the organic emission layer may be improved. In addition, a diffusion range in evaporation of the transfer layer may be limited by a side wall of the concave groove, and the organic emission layer may be formed with a uniform thickness in the pixel without interrupting a neighboring pixel. Accordingly, color purity, color life-span, and luminous efficiency may be improved, and light emission uniformity in the pixel may be improved.

For example, according to an embodiment, both the absorption layer and the reflection layer may be patterned. The absorption layer and the reflection layer may not be positioned on the non-deposition pixel area, and the absorption layer and the reflection layer may be separated as far away from each other as possible. The surface of the absorption layer may have a shape of a well, and a groove may be formed below the PDL/spacer. According to the above structure, conduction of heat of the light-to-heat conversion layer during the transfer process may be minimized so that pattern precision of the organic emission layer can be improved. In addition, a diffusion range in evaporation of the transfer layer may be limited by a side wall of the concave groove, and the organic emission layer may be formed with a uniform thickness in the pixel without interrupting or interfering with a neighboring pixel.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A donor substrate for transfer, the donor substrate comprising:
a transparent support layer;
a light-to-heat conversion layer on one side of the support layer, the light to heat conversion layer being in the form of a first pattern;
a transfer layer covering the light-to-heat conversion layer; and
a reflection layer on another side of the support layer, the other side being opposite to the one side of the support layer, the reflection layer being in the form of a second pattern.

2. The donor substrate for transfer as claimed in claim 1, wherein:
the first pattern is the same as a pattern of a transfer target, and
the second pattern includes an opening aligned with the first pattern.

3. The donor substrate for transfer as claimed in claim 2, wherein:
the transfer layer includes an organic light emitting material, and
the first pattern of the light-to-heat conversion layer has the same shape and the same size as a size and shape as transfer target organic emission layers.

4. The donor substrate for transfer as claimed in claim 3, wherein:
the support layer includes a plurality of concave grooves, and
the light-to-heat conversion layer and the transfer layer are formed in each of the plurality of concave grooves.

5. The donor substrate for transfer as claimed in claim 4, wherein the support layer includes a groove portion between the plurality of concave grooves, the groove portion having a depth larger than a depth of each of the plurality of concave grooves.

6. The donor substrate for transfer as claimed in claim 2, wherein:
the transfer layer includes a metal material, and
the first pattern of the light-to-heat conversion layer has the same shape as a transfer target auxiliary electrode.

7. The donor substrate for transfer as claimed in claim 6, wherein:
the support layer includes a concave groove, and
the light-to-heat conversion layer and the transfer layer are formed in the concave groove.

8. The donor substrate for transfer as claimed in claim 7, wherein the concave groove and the first pattern of the light-to-heat conversion have a shape of a stripe or a lattice.

9. The donor substrate for transfer as claimed in claim 1, wherein the support layer includes one of glass, quartz, or a polymer material.

10. A manufacturing method of an organic light emitting diode (OLED) display, the method comprising:
forming a pixel electrode and a pixel defining layer on a substrate;
preparing a first donor substrate for transfer such that the first donor substrate for transfer includes:
a support layer,
a light-to-heat conversion layer on one side of the support layer, the light to heat conversion layer having a same shape as an organic emission layer to be formed,
a transfer layer covering the light-to-heat transfer layer, and
a reflection layer on another side of the support layer, the other side being opposite to the one side of the support layer, the reflection layer including an opening aligned with the light-to-heat conversion layer;
arranging the first donor substrate for transfer on the substrate such that the light-to-heat conversion layer and the transfer layer face the pixel electrode; and
irradiating light to the first donor substrate for transfer and forming the organic emission layer by transferring the transfer layer onto the pixel electrode using heat from the light-to-heat conversion layer.

11. The manufacturing method of the OLED display as claimed in claim 10, wherein:
the support layer includes a plurality of concave grooves, and
the light-to-heat conversion layer and the transfer layer are formed in each of the plurality of concave grooves.

12. The manufacturing method of the OLED display as claimed in claim 11, further comprising forming a spacer on the pixel defining layer, and forming a groove portion in the support layer, such that arranging the first donor substrate for transfer on the substrate causes the groove portion to face the spacer.

13. The manufacturing method of the OLED display as claimed in claim 12, wherein:
a width of the groove portion is smaller than a width of each of the concave grooves, and
a depth of the groove portion is greater than a depth of each of the concave grooves.

14. The manufacturing method of the OLED display as claimed in claim 10, further comprising:
forming a common electrode on the organic emission layer;
preparing a second donor substrate for transfer such that the second donor substrate for transfer includes:
a support layer,
a light-to-heat conversion layer on one side of the support layer, the light-to-heat conversion layer having a same shape as an auxiliary electrode to be formed,
a transfer layer covering the light-to-heat conversion layer, and
a reflection layer on another side of the support layer, the other side being opposite to the one side of the support layer, the reflection layer including an opening aligned with the light-to-heat conversion layer;
arranging the second donor substrate for transfer on the substrate such that the light-to-heat conversion layer and the transfer layer face the common electrode; and
irradiating light to the second donor substrate for transfer and forming the auxiliary electrode by transferring the transfer layer onto to the common electrode using heat from the light-to-heat conversion layer.

15. The manufacturing method of the OLED display as claimed in claim 14, wherein:
the support layer includes a concave groove, and
the light-to-heat conversion layer and the transfer layer are formed in the concave groove.

16. The manufacturing method of the OLED display as claimed in claim 15, wherein the concave groove and the light-to-heat conversion layer have a shape of a stripe or a lattice.
